(19) United States
(12) Patent Application Publication
(10) Pub. No.: US 2010/0128440 A1
(43) Pub. Date: May 27, 2010

(54) HEAT SINK ASSEMBLY HAVING A CLIP

(75) Inventors: Min Li, Shenzhen City (CN); Hui Xia, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 12/399,033

(22) Filed: Mar. 6, 2009

(30) Foreign Application Priority Data
Nov. 21, 2008 (CN) 200820302879.5

(51) Int. Cl. H05K 7/20

(52) U.S. Cl. 361/709

(57) ABSTRACT

A heat sink assembly includes a heat sink and a clip. The heat sink includes a base and two first and two second fins mounted on a top surface of the base. The first and second fins are spaced from each other. The first fins are located between the second fins. Each second fin includes a body and a ridge formed at an inner surface of the body. The clip includes a pressing member, two engaging members angling upwardly from opposite ends of the pressing member, and two locking members extending from ends of the engaging members respectively. The pressing member of the clip is sandwiched between the first fins and abuts the top surface of the base. The engaging members of the clip span the first fins and resist the ridges and the second fins respectively.

### BACKGROUND OF THE INVENTION

1. Field of the Invention

The present invention relates to heat sink assemblies and, more particularly, to a heat sink assembly having a clip which can be easily and accurately assembled to the heat sink.

2. Description of Related Art

A heat sink assembly cools an electronic device. The heat sink assembly generally includes a heat sink attached to an outer surface of the electronic device to facilitate dissipation of heat therefrom and a clip fastening the heat sink to the electronic device. The heat sink includes a base and a plurality of fins extending therefrom. A channel is defined between every two adjacent fins. The clip extends through one of the channels and abuts a top surface of the base.

When the clip is mounted on the heat sink, the heat sink is punched by a tool to have a portion thereof deformed to engage with the clip. The punched part of the heat sink may be broken from the heat sink during the punching process whereby the clip cannot be attached to the heat sink. On the other hand, the punched part may too tightly engage with the clip, whereby the clip can not properly rotate relative to the heat sink and accordingly cannot properly secure the heat sink to the electronic device.

What is needed, therefore, is a heat sink assembly having a clip which can be easily and accurately assembled to the heat sink to solve the problems of the prior art mentioned above.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an assembled view of a heat sink assembly in accordance with an embodiment of the disclosure, wherein the heat sink assembly is assembled to a printed circuit board.

FIG. 2 is an exploded view of the heat sink assembly of FIG. 1, wherein the heat sink assembly is disassembled from the printed circuit board.

FIG. 3 is cutaway view of the heat sink assembly of FIG. 1.

FIG. 4 is a side view of the heat sink assembly, wherein a clip of the heat sink assembly is unlocked.

FIG. 5 is a side view of the heat sink assembly, wherein the clip of the heat sink assembly is locked.

### DETAILED DESCRIPTION OF THE DISCLOSURE

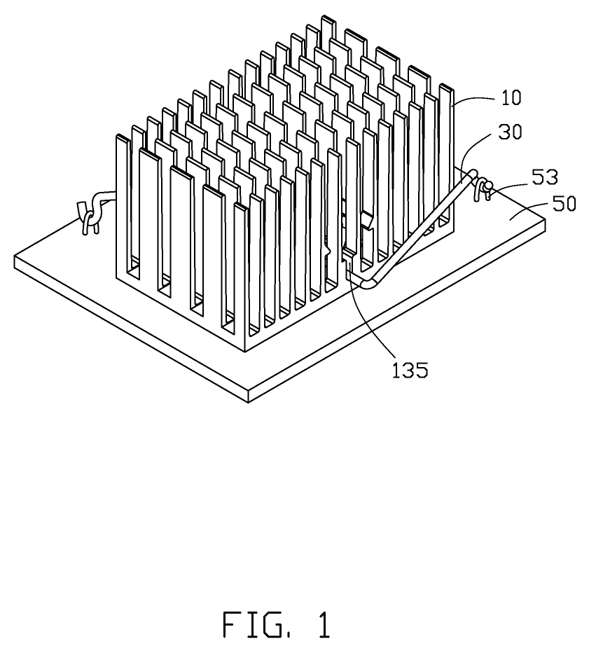

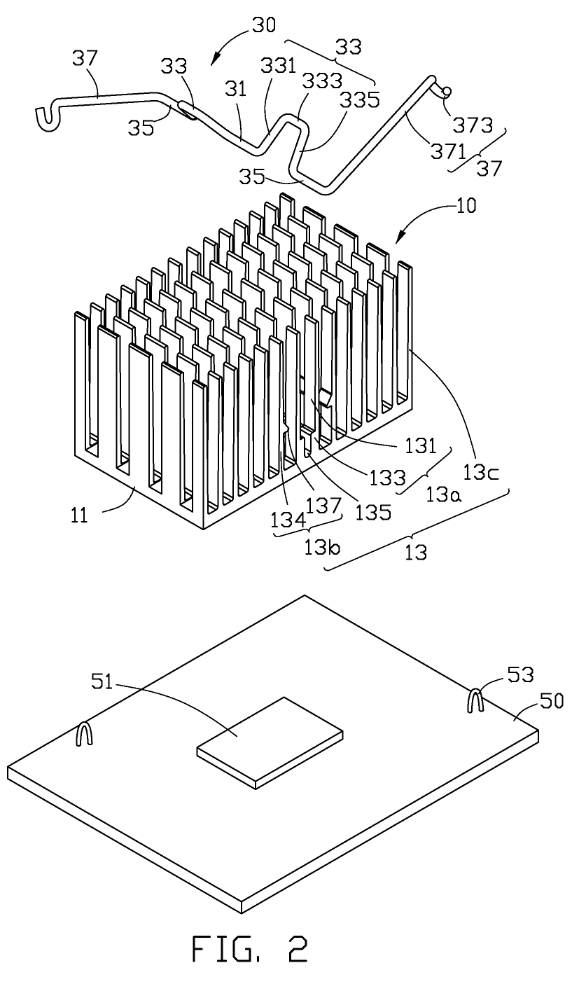

Referring to FIGS. 1-2, a heat sink assembly comprises a heat sink 10 and a clip 30. The heat sink 10 thermally contacts an electronic element 51 on a printed circuit board 50. The clip 30 spans the heat sink 10 and engages with two clasps 53 located on the printed circuit board 50 and near two diagonal corners of the heat sink 10 to secure the heat sink 10 on the printed circuit board 50.

The heat sink 10 is integrally made of metal with high heat conductivity such as copper, aluminum or an alloy thereof. The heat sink 10 comprises a rectangular base 11 and a plurality of fins 13 extending upwardly from a top surface of the base 11. The fins 13 are parallel and spaced from each other to constitute a plurality of rows. An elongated channel (not labeled) is defined between every two adjacent rows of fins 13 along a width or a length axis of the base 11. The fins 13 comprise two rows of first fins 13a, two rows of second fins 13b, and a plurality of rows of third fins 13c. The first, second and third fins 13a, 13b, 13c are arranged in neat rows along the width axis of the base 11 of the heat sink 10. The first, second and third fins 13a, 13b, 13c are symmetrical about a central surface at a center of the heat sink 10 along the width axis of the base 11 and perpendicular to the top surface of the base 11.

The first fins 13a are located at a central portion of the base 11 of the heat sink 10. Each of the first fins 13a comprises an elongated first fin body 131 and a protrusion 133 extending inwardly from an inner surface thereof. The protrusions 133 facing each other are formed at lower portions of the adjacent first fins 13a of the two rows. The protrusions 133 define a straight groove 135 therebetween, receiving the clip 30 therein. The groove 135 is narrower than a gap between top portions of the first fins 13a. Strength of the lower portions of the first fins 13a is reinforced by the protrusions 133.

The two rows of second fins 13b are located at opposite sides of the first fins 13a. Each of the second fins 13b comprises an elongated second fin body 134 and a cuneate ridge 137 angling downwardly and inwardly from an inner surface of the second fin body 134. The ridges 137 of the two second fins 13b face the first fins 13a. The ridges 137 are disposed at the same height above the protrusions 133 of the first fins 13a. The ridges 137 abut downwardly against the clip 30 when the clip 30 is mounted to the heat sink 10. The third fins 13c are elongated and located at opposite sides of second fins 13b. The first, second and third fins 13a, 13b, 13c cooperatively dissipate heat from the heat sink 10.

The clip 30 is a wire clip integrally made of metal wire. The clip 30 comprises a straight pressing member 31, two trapezoidal engaging members 33 angling upwardly from opposite ends of the pressing member 31 toward two different directions, two straight extending members 35 extending outwardly from free ends of the engaging members 33, and two locking arms 37 perpendicularly extending outwardly from free ends of the extending members 35 and oriented towards generally opposite directions. The clip 30 is symmetrical about the pressing member 31.

The pressing member 31 of the clip 30 is snugly received in the groove 135 between the first fins 13a of the heat sink 10. The engaging members 33 of the clip 30 are spaced from each other. Each of the engaging members 33 comprises a straight resisting portion 333, a first connecting portion 331 and a second connecting portion 335. The resisting portion 333 is located at a side of the pressing member 31. The first connecting portion 331 angles downwardly from an inner end of the resisting portion 333 and connects with an end of the pressing member 31. The second connecting portion 335 angles downwardly from an outer end of the resisting portion 333 and connects with an end of the extending member 35. The resisting portions 333 of the two engaging members 33 are on opposite sides of the pressing member 31 and parallel thereto. The resisting portions 333 abut the ridges 137 and the inner surfaces of the second fins 13b of the heat sink 10 to prevent movement thereof along the length axis of the base 11 thereof. The first and second connecting portions 331, 335 of each of the two engaging members 33 sandwich one of the corresponding first fins 13a of the fins 13 of the heat sink 10 therebetween to prevent the heat sink 10 from moving along the width axis of the base 11 of the heat sink 10. Here, a distance between the first and second connecting portions 331, 335 of each of the two engaging members 33 approaches a width of each first fin 13a of the fins 13.

The extending members 35 of the clip 30 and the pressing member 31 of the clip 30 are collinear and disposed at the same height. The locking member 37 comprises a straight locking arm 371 and a hook 373 angling laterally from a free end of the locking arm 371. The locking arms 371 are perpendicular to the extending members 35. The two locking arms 371 extend towards different directions. The hooks 373 engage the clasps 53 of the printed circuit board 50, when the clip 20 is used to secure the heat sink 10 to the printed circuit board 50 so that the heat sink 10 can intimately engage with the electronic element 51.

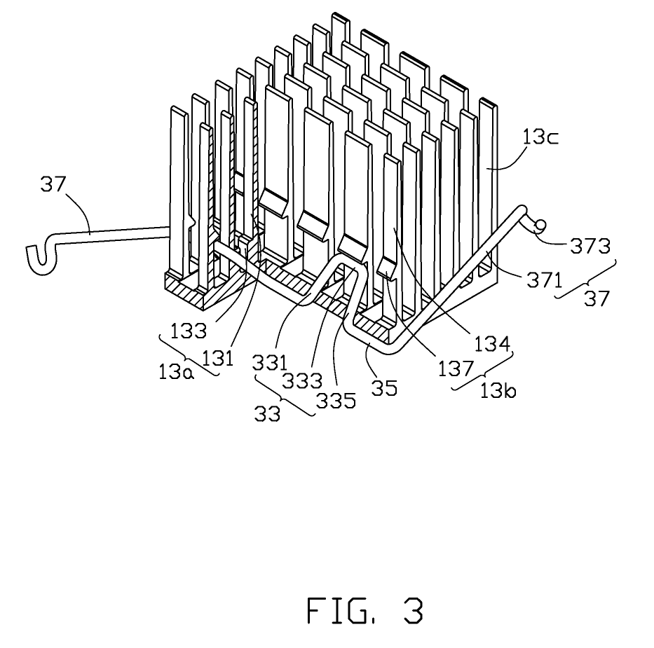

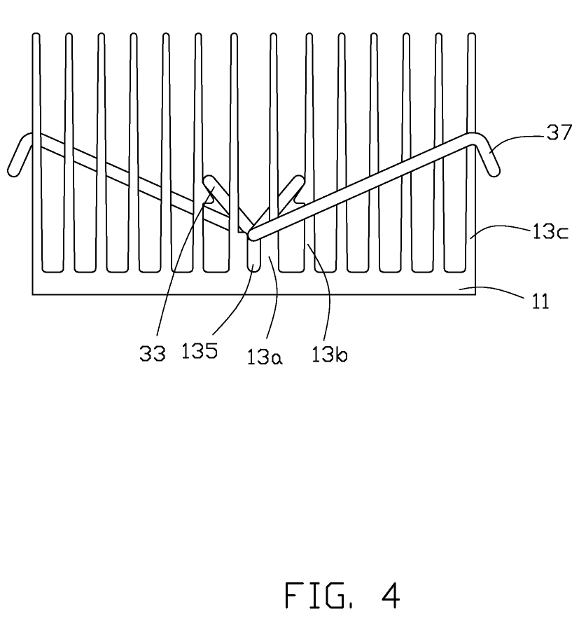

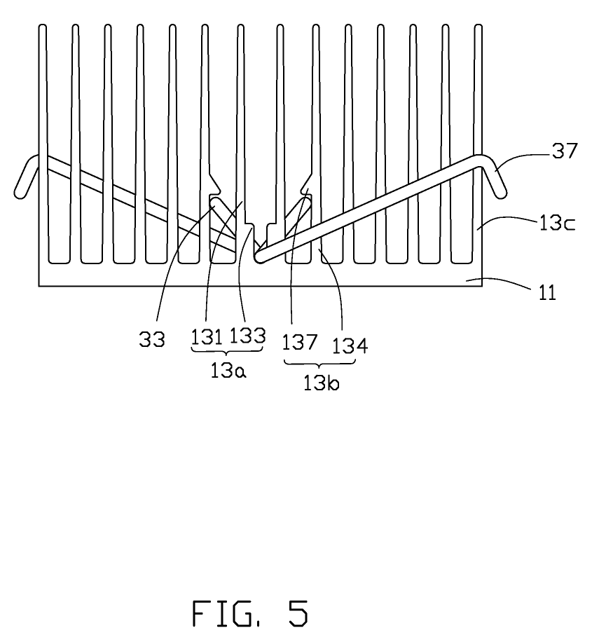

Referring to FIGS. 3-5 also, in assembly, the heat sink 10 is disposed on a top surface of the electronic element 51 of the printed circuit board 50. The clip 30 is arranged on the top surface of the base 11 from top to bottom of the fins 13. Thus, the pressing member 31 of the clip 30 extends through the first fins 13a of the fins 13 of the heat sink 10 and is pivotably engaged in the groove 135 of the heat sink 10. Each of the resisting members 33 spans the corresponding first fin 13a of the fins 13 of the heat sink 10 and abuts an inclined top surface of the corresponding ridge 137 of the second fin 13b of the fins 13 of the heat sink 10. In this state, one first fin 13a is sandwiched between the first and second connecting portions 331, 335 of one corresponding engaging member 33. Inner ends of the extending members 35 are pivotably engaged in the groove 135 of the heat sink 10. Outer ends of the extending members 35 and the locking members 37 are beyond the base 11 and located at lateral sides of the base 11 of the heat sink 10. The locking arms 371 of the locking members 37 are pressed downwardly until the hooks 373 of the locking members 37 engage the clasps 53 of the printed circuit board 50. Meanwhile, the extending members 35 rotate along opposite directions, the resisting portions 333 of the engaging members 33 slip downwardly along the inclined top surfaces of the ridges 137 of the second fins 13b of the fins 13 of the heat sink 10 until the resisting portions 333 are received in angles defined by bottom ends of the ridges 137 and the second fins 13b. Thus, the clip 30 provides a steady locking force to maintain tight attachment of the heat sink 10 to the electronic element 51 of the printed circuit board 50. As a result, the heat sink 10 is fixed on the printed circuit board 50 to have intimate contact with the electronic element 51. In the present disclosure, the heat sink 10 does not need being punched in order to mount the clip 30 to the heat sink 10; thus, the disadvantages of the prior can be avoided by the present disclosure.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1 A heat sink assembly, comprising:
a heat sink comprising a base and two first fins and two second fins extending upwardly from a top surface of the base, the first and second fins spaced from each other, the two first fins located between the two second fins, and wherein each of the two second fins comprises a body and a ridge formed at an inner surface of the body and facing the two first fins; and
a clip comprising a pressing member, two engaging members angling upwardly from two opposite ends of the pressing member and located on opposite sides of the pressing member, and two locking members extending from two ends of the engaging members respectively;
wherein the pressing member of the clip is sandwiched between the first fins and abuts the top surface of the base of the heat sink, the engaging members of the clip span the first fins located at opposite sides respectively and resist bottom ends of the ridges and corresponding second fins of the heat sink respectively.

2. The heat sink assembly as claimed in claim 1, wherein the two engaging members of the clip enclose the first fins therein.

3. The heat sink assembly as claimed in claim 2, wherein each of the two engaging members comprises a resisting portion resisting a corresponding one of the ridges and a corresponding one of the second fins of the heat sink and two connecting portions angling downward from opposite ends of the resisting portion, and a corresponding one of the first fins being sandwiched between the two connecting portions.

4. The heat sink assembly as claimed in claim 3, wherein each of the two engaging members of the clip has a trapezoidal configuration.

5. The heat sink assembly as claimed in claim 1, wherein each of the ridges of the second fins has a cuneate configuration.

6. The heat sink assembly as claimed in claim 1, wherein two straight extending members of the clip extend outwardly from two ends of the two engaging members respectively and connect with the locking members.

7. The heat sink assembly as claimed in claim 6, wherein a part of each of the extending members of the clip is beyond the heat sink.

8. The heat sink assembly as claimed in claim 1, wherein each the locking members of the clip comprises a straight locking arm and a hook angling laterally from an end of the each locking arm, the two locking arms of the two locking members extending along substantially opposite directions.

9. The heat sink assembly as claimed in claim 1, wherein each of the first fins comprises a body and a protrusion extending inwardly from an inner surface of the body, with the protrusions of two rows of adjacent first fins facing each other and sandwiching the pressing member of the clip therebetween.

10. The heat sink assembly as claimed in claim 9, wherein the ridges of the second fins are disposed at the same height and above the protrusions of the first fins.

11. The heat sink assembly as claimed in claim 1, wherein the first and second fins are symmetrical about a central surface at a center of the heat sink, along a width axis of the base and perpendicular to the top surface of the base.

12. The heat sink assembly as claimed in claim 1, wherein the clip is symmetrical about a center of the pressing member.
